(19) United States
(12) Patent Application Publication
(10) Pub. No.: US 2011/0303282 A1
(43) Pub. Date: Dec. 15, 2011

(54) SOLAR GLASS AND MANUFACTURING METHOD THEREOF

(75) Inventors: Cheng-Han Tsai, Tainan (TW); Wen-Ping Yang, Tainan (TW)

(73) Assignee: AURIA SOLAR CO., LTD., Tainan (TW)

(21) Appl. No.: 13/216,128

(22) Filed: Aug. 23, 2011

(30) Foreign Application Priority Data
May 4, 2011 (TW) 100115667

(51) Int. Cl. H01L 31/0232; H01L 31/18

(52) U.S. Cl. 136/256; 438/70; 257/E31.127

(57) ABSTRACT

A solar glass is used for building-integrated photovoltaic (BIPV). From a light-incident side to a light-emitting side, the solar glass sequentially includes a front substrate, a first electrode layer, a photoelectric conversion layer, a second electrode layer, a low emissivity (Low-E) film, and a back substrate. The photoelectric conversion layer is used for receiving light energy and converting the light energy into electric energy. The Low-E film allows visible light to pass through and reflects infrared light. By using a structure of the solar glass, the thickness of the solar glass may be greatly reduced.

### CROSS-REFERENCE TO RELATED APPLICATIONS

This non-provisional application claims priority under 35 U.S.C. §119(a) on Patent Application No(s). 100115667 filed in Taiwan, R.O.C. on May 4, 2011, the entire contents of which are hereby incorporated by reference.

### BACKGROUND

1. Technical Field

The disclosure relates to a glass, and more particularly to a solar glass.

2. Related Art

Building-integrated photovoltaic (BIPV) is defined as a technology of replacing building materials with photovoltaic materials, so that the building, made by photovoltaic materials, can produce electricity out of sunlight. Besides, because solar cells are incorporated into the building materials, for example, exterior wall tiles, glass curtains, and roof tiles, the building also has esthetic appearance. Furthermore, the electricity generated by the building may not only be used by the building, but the remaining power may also be sold to power companies. These factors make the BIPV become one of the fastest developed solar cell technologies.

When ordinary glass curtains are used in a building, a large amount of solar radiation heat may be transferred into the room through the glass, which inevitably increases the load of the air conditioner of the building and, therefore, causes more energy consumption. Therefore, a glass capable of energy conservation is proposed to reduce the radiation heat entering the room through the glass, thereby achieving the purpose of energy conservation.

Currently, a BIPV glass curtain has a vacuum layer disposed between a photovoltaic layer and a back substrate. The vacuum layer may isolate heat transfer, so that the heat energy of solar irradiation cannot be directly transferred into the room. However, the BIPV glass curtain having the vacuum layer is thicker and is thus not easy to be transported. In addition, the increase of the thickness of the glass curtain may also cause inconvenience in assembling other building material and the thick glass curtain together when a building is constructed.

### SUMMARY

According to an embodiment, a solar glass comprising a front substrate, a first electrode layer, a photoelectric conversion layer, a second electrode layer, a low emissivity (Low-E) film, and a back substrate is disclosed.

The first electrode layer is disposed at one side of the front substrate.

The photoelectric conversion layer is used for receiving light energy and converting the light energy into electric energy.

The first electrode layer and the second electrode layer are disposed at two opposite sides of the photoelectric conversion layer.

The Low-E film is disposed at one side of the second electrode layer opposite to the photoelectric conversion layer, and the Low-E film allows visible light to pass through and reflects infrared light.

The back substrate is disposed at one side of the Low-E film opposite to the photoelectric conversion layer.

Furthermore, the disclosure provides a manufacturing method of a solar glass. The method comprises: providing a front substrate; forming a first electrode layer on the front substrate; forming a photoelectric conversion layer on the first electrode layer; forming a second electrode layer on the photoelectric conversion layer; plating a Low-E film which allows visible light to pass through and reflects infrared light on one side of a back substrate,; and forming the back substrate on the second electrode layer, so that the Low-E film is located between the back substrate and the second electrode layer.

Through the solar glass and the manufacturing method of the solar glass, the thickness of the glass can be greatly reduced so as to improve the convenience of glass delivery or construction of a structure.

### BRIEF DESCRIPTION OF THE DRAWINGS

Unless otherwise specified, the same reference numbers are used throughout the drawings to refer to the same or like elements of embodiments, and wherein:

FIG. 1 is a sectional structural view of a solar glass according to an embodiment; and

FIG. 2 is a flow chart of a manufacturing method of a solar glass according to an embodiment.

### DETAILED DESCRIPTION

In the following description, for purpose of explanation, numerous specific details are set forth in order to provide a thorough understanding of the detailed embodiments. It will be apparent, however, that one or more embodiments may be practiced without these specific details. In other instances, well-known structures and elements are schematically shown in order to simplify the drawings.

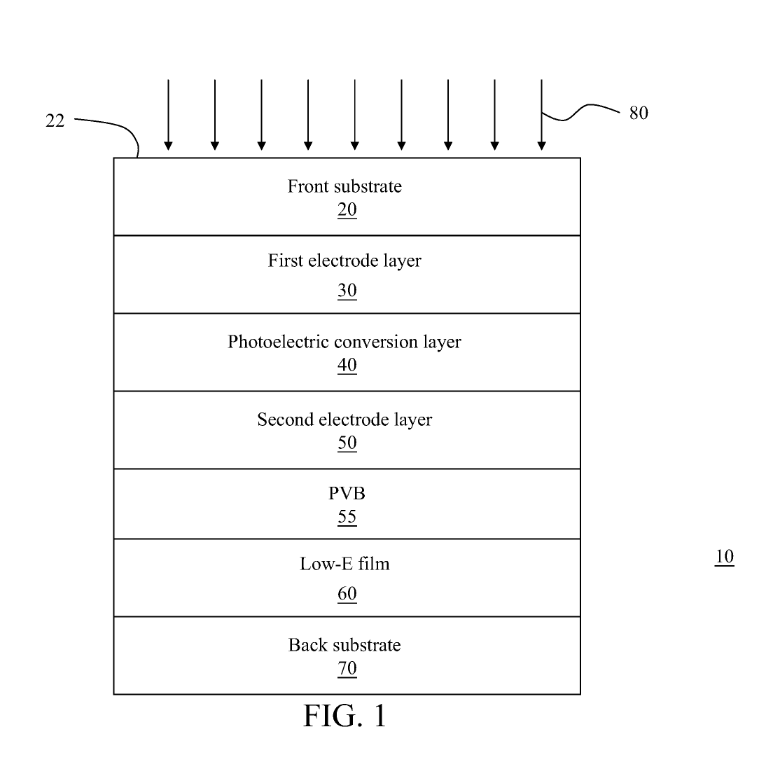

FIG. 1 is a sectional structural view of a solar glass according to an embodiment.

As shown in FIG. 1, the solar glass 10 comprises a front substrate 20, a first electrode layer 30, a photoelectric conversion layer 40, a second electrode layer 50, a Low-E film 60, and a back substrate 70.

The front substrate 20 may be a transparent substrate, and the material of the transparent substrate may be, but not limited to, glass or transparent resin. One side of the front substrate 20 is a light-incident side 22, and sunlight 80 is incident on the solar glass 10 from the light-incident side 21.

The first electrode layer 30 is disposed at one side of the front substrate 20 opposite to the light-incident side 21. The material of the first electrode layer 30 may be transparent conductive oxide (TCO), and the TCO may be, but not limited to, zinc oxide (ZnO) or other transparent conductive materials.

The photoelectric conversion layer 40 is located at one side of the first electrode layer 30. The photoelectric conversion layer 40 is used for receiving light energy and converting the light energy into electricity. The material of the photoelectric conversion layer 40 may be, but not limited to, amorphous silicon (a-Si), microcrystalline silicon (μc-Si), polycrystalline silicon, cadmium telluride (CdTe), organic material or a multi-layer structure of at least two of the above mentioned materials. Furthermore, the photoelectric conversion layer 40 may be a PIN semiconductor structure having a P-type semiconductor layer, an N-type semiconductor layer, and an intrinsic layer, or a PN semiconductor structure without the intrinsic layer.

The second electrode layer 50 is located at the other side of the photoelectric conversion layer 40. That is to say, the first electrode layer 30 and the second electrode layer 50 are respectively disposed on two opposite sides of the photoelectric conversion layer.

The Low-E film 60 is disposed on one side of the second electrode layer 50 opposite to the photoelectric conversion layer 40. The Low-E film 60 allows visible light to pass through and reflects infrared light. In this embodiment, to adhere the Low-E film 60 to the second electrode layer 50, a Polyvinyl butyral (PVB) layer 55 is used. However, this embodiment is not intended to limit methods for combining the Low-E film 60 and the second electrode layer 50 together. In some embodiments, adhesive material with good optical clarity may be used.

In some embodiments, the Low-E film is an oxide metal layer, and the oxide metal layer may be, but not limited to, titanium-base metal.

Generally, in sunlight, infrared rays account for approximately 51.2% of the total energy of the sunlight, visible light accounts for approximately 46.8% of the total energy, and ultraviolet rays and other rays account for approximately 2% of the total energy. The Low-E film 60 has a metal surface, and the Low-E film 60 has a very high reflectivity for far-infrared rays having wavelengths of 780 nm to 3000 nm and more than 3000 nm, so the Low-E film 60 may block out the infrared rays in the sunlight. On the other hand, the light blocking rate of the Low-E film 60 is very low for visible light, of which the wavelength ranges from 380 nm to 760 nm, and, therefore, the visible light are allowed to pass through the Low-E film 60 so as to ensure a good light-transmissive characteristic of the solar glass 10. Therefore, the purpose of reducing energy consumption of the indoor air-conditioner is achieved by blocking the heat from entering the room. Besides, the transmittance of ultraviolet rays is greatly reduced, which largely increases the comfort of people in the building.

The back substrate 70 is disposed on one side of the Low-E film 60 opposite to the photoelectric conversion layer 40. The back substrate 70 may be a transparent substrate, and the material of the transparent substrate may be, but not limited to, glass or transparent resin.

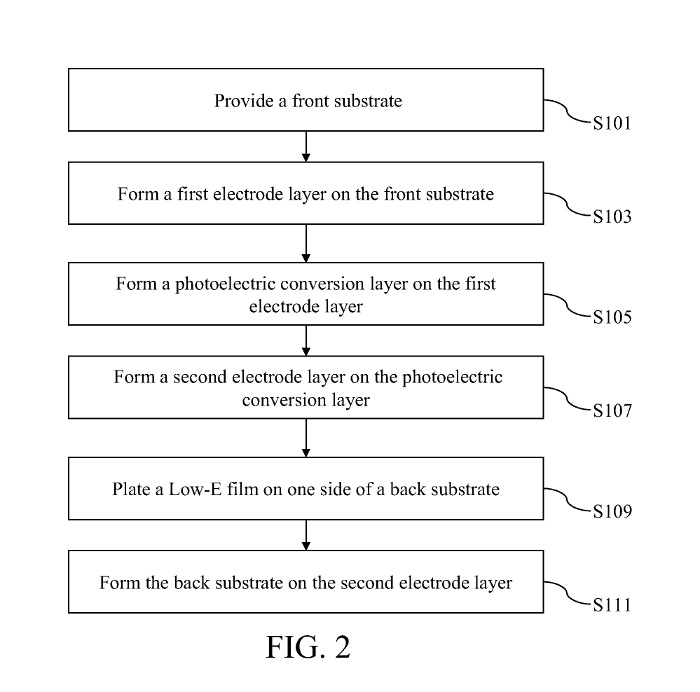

FIG. 2 is a flow chart of a manufacturing method, which comprises the following steps, of a solar glass according to an embodiment.

In Step S101, a front substrate is provided.

In Step S103, a first electrode layer is formed on the front substrate.

In this embodiment, for forming the first electrode layer, an electron beam evaporation method, a physical vapor deposition (PVD) method, or a sputtering deposition method may be adopted.

In Step S105, a photoelectric conversion layer is formed on the first electrode layer.

In this embodiment, the photoelectric conversion layer may be formed by a chemical vapor deposition (CVD) method, such as radio frequency plasma enhanced chemical vapor deposition (RF PECVD) method, very high frequency plasma enhanced chemical vapor deposition (VHF PECVD) method, or microwave plasma enhanced chemical vapor deposition (MW PECVD) method.

In Step S107, a second electrode layer is formed on the photoelectric conversion layer.

In this embodiment, for forming the second electrode layer, the electron beam evaporation method, the PVD method, or the sputtering deposition method may be used.

In Step S109, a Low-E film is plated on one side of a back substrate, and the Low-E film allows visible light to pass through and reflects infrared light.

The Low-E film may be plated in an on-line plating method or an off-line plating method.

The on-line plating method may be used to fabricating hard low-E glass, which may be sorted into a monolithic type, an agglutination type, and a multi-layer type. Because the hard low-E glass may directly go through a high-temperature strengthening process or a bending process, it is thus convenient in use. The plating of the Low-E film mainly employs a pyrolytic process. After glass paste is delivered out of a furnace, the Low-E film material is sprayed on a shaped high-temperature plate glass, and then the film material is plated on the plate glass through the pyrolytic process. The Low-E film plating is performed during the glass fabrication process, and is thus referred to as on-line Low-E film plating. The on-line plating method is mainly characterized in that the process is simple, the cost is low, and the hard Low-E glass may be reinforced and used in the monolithic type.

As for soft Low-E glass plated through the off-line plating method, the plated metal layer is not high-temperature resistant, and because the plated metal layer is easily oxidized, the plated metal layer is not suitable to be exposed in air for a long time. However, due to the plated metal layer has excellent heat insulation property, the plated metal layer is desirable for manufacturing multi-layer glass materials. The off-line plating method forms multi-layer metal or ceramic (oxidized metal) films on a plate glass by sputtering or magnetron sputtering during a vacuum plating process. Because the ion incident kinetic energy in the magnetron sputtering method is high, the packing factor (relevant to the refraction index) of the soft Low-E film is also high. The soft Low-E glass is mainly characterized in that the energy conservation effect is excellent, the energy conservation effect can be adjusted according to different geographic environments of the building, and the soft Low-E glass may also be reinforced and have a lot of colors and types, which may satisfy the expectations of designers and proprietors.

In Step S111, the back substrate is formed on the second electrode layer so that the Low-E film is located between the back substrate and the second electrode layer.

According to the disclosure, through the solar glass and the manufacturing method of the solar glass, the thickness of the glass may be greatly reduced so as to improve the convenience of glass delivery or building construction.

What is claimed is:

1. A solar glass, comprising:
a front substrate;
a first electrode layer, disposed at one side of the front substrate;
a photoelectric conversion layer, for receiving light and converting the light into electricity;
a second electrode layer, the first electrode layer and the second electrode layer being respectively disposed on two opposite sides of the photoelectric conversion layer;
a low emissivity (Low-E) film, disposed on one side of the second electrode layer opposite to the photoelectric conversion layer, and the Low-E film allowing visible light to pass through and reflecting infrared light; and
a back substrate, disposed on one side of the Low-E film opposite to the photoelectric conversion layer.

2. The solar glass according to claim 1, wherein the photoelectric conversion layer comprises an amorphous silicon (a-Si) photoelectric conversion layer and a microcrystalline silicon (μc-Si) photoelectric conversion layer.

3. The solar glass according to claim 1, wherein the Low-E film is oxide metal.

4. The solar glass according to claim 3, wherein the oxide metal layer is titanium-base metal.

5. A manufacturing method of a solar glass, comprising:
providing a front substrate;
forming a first electrode layer on the front substrate;
forming a photoelectric conversion layer on the first electrode layer;
forming a second electrode layer on the photoelectric conversion layer;
plating a low emissivity (Low-E) film on one side of a back substrate, the Low-E film allowing visible light to pass through, and reflecting infrared light; and
forming the back substrate on the second electrode layer for disposing the Low-E film between the back substrate and the second electrode layer.

6. The manufacturing method of the solar glass according to claim 5, wherein in the step of plating the Low-E film on one side of the back substrate, the Low-E film is sprayed on the back substrate, and then plated on the back substrate by using a pyrolytic process.

7. The manufacturing method of the solar glass according to claim 6, wherein the Low-E film is an oxide metal layer.

8. The manufacturing method of the solar glass according to claim 5, wherein in the step of plating the Low-E film on one side of the back substrate, the Low-E film is plated on the back substrate by using a sputtering method or a magnetron sputtering method.

9. The manufacturing method of the solar glass according to claim 8, wherein the Low-E film is an oxide metal layer.
